(19) United States
(12) Patent Application Publication
(10) Pub. No.: US 2025/0275340 A1
(43) Pub. Date: Aug. 28, 2025

(54) Metal Ring and Encapsulation for Passivation of Light-Emitting Diode Display Pixels

(71) Applicant: Apple Inc., Cupertino, CA (US)

(72) Inventors: Xin Zhao, San Jose, CA (US); Sandeep Chalasani, San Jose, CA (US); Steven E. Molesa, San Jose, CA (US); Weixin Li, Sunnyvale, CA (US); Joy M. Johnson, Oakland, CA (US); Anatole Huang, Campbell, CA (US); Bhadrinarayana Lalgudi Visweswaran, Santa Clara, CA (US); Camila de Paula Teixeira, Santa Clara, CA (US); Kyungyong Choi, Sunnyvale, CA (US); Prashant Mandlik, Sunnyvale, CA (US); Allen C. Fung, San Francisco, CA (US); Chia-Hsin Lin, Taichung City (TW); Ying-Hua Chen, HsinChu (TW); Zhen Zhang, Sunnyvale, CA (US); Bulong Wu, San Jose, CA (US); Chin Wei Hsu, Hsinchu (TW)

(21) Appl. No.: 19/035,139

(22) Filed: Jan. 23, 2025

Related U.S. Application Data
(60) Provisional application No. 63/558,024, filed on Feb. 26, 2024.

(51) Int. Cl. H10H 29/80; H01L 25/16; H10H 29/37; H10H 29/39; H10H 29/41; H10H 29/49; H10H 29/852

(52) U.S. Cl. CPC H10H 29/842; H01L 25/167; H10H 29/37; H10H 29/39; H10H 29/41; H10H 29/49; H10H 29/852

(57) ABSTRACT

An electronic device and methods of fabrication are disclosed. In an embodiment, an electronic device includes a display panel including a display area, a peripheral edge surrounding the display area, and a border region along the peripheral edge and surrounding the display area. The display panel may further include an array of pixel driver chips, a redistribution layer (RDL) over the array of pixel driver chips, and an array of light-emitting diodes (LEDs) mounted on the RDL within the display area, where the RDL includes a metal seal ring in the border region.

### RELATED APPLICATIONS

This application claims the benefit of priority of U.S. Provisional Application No. 63/558,024, filed Feb. 26, 2024, which is incorporated herein by reference.

### BACKGROUND

### Field

Embodiments described herein relate to display structures, and more particularly to sealing structures.

### Background Information

Display panels are utilized in a wide range of electronic devices. Conventional organic light-emitting diode (OLED) or liquid crystal display (LCD) technologies feature a thin film transistor (TFT) substrate. More recently, it has been proposed to replace the TFT substrate with an array of pixel driver chips (also referred to as micro driver chips, or microcontroller chips) bonded to a substrate and to integrate an array of micro LEDs with the array of pixel driver chips, where each pixel driver chip is to switch and drive a corresponding plurality of the micro LEDs. Routing between the pixel driver chips and the micro LEDs may be provided with a redistribution layer (RDL) for example.

### SUMMARY

An electronic device and methods of fabrication are disclosed. In an embodiment, an electronic device includes a display panel including a display area, a peripheral edge surrounding the display area, and a border region along the peripheral edge and surrounding the display area. The display panel may further include an array of pixel driver chips, a redistribution layer (RDL) over the array of pixel driver chips, and an array of light-emitting diodes (LEDs) mounted on the RDL within the display area, where the RDL includes a metal seal ring in the border region. The metal seal ring may be joined to an underlying sealing layer and an overlying sealing layer to provide a sealed box structure for the RDL to protect against moisture ingress and provide mechanical integrity.

### BRIEF DESCRIPTION OF THE DRAWINGS

FIG. 1 is schematic top view illustration of a tile-based display panel with a cutout and spline-corners in accordance with an embodiment.

FIG. 2 is a schematic top view illustration of a matrix tile including a pixel driver chip to switch and drive multiple pixels of LEDs in accordance with an embodiment.

FIG. 3 is a close-up schematic cross-sectional side view illustration of a portion of display panel including an RDL sealing structure in accordance with an embodiment.

FIG. 4 is a close-up schematic cross-sectional side view illustration of a portion of display panel including an RDL sealing structure in which the RDL has a reduced thickness in the border region in accordance with an embodiment.

FIGS. 5-7 are schematic top plan view illustrations of display panels including various metal seal ring locations in accordance with embodiments.

FIG. 8 is a close-up schematic cross-sectional side view illustration of a portion of display panel including an RDL sealing structure accordance with an embodiment.

FIG. 9 is a close-up schematic cross-sectional side view illustration of a portion of display panel including an RDL sealing structure extending beneath the pixel driver chips in accordance with an embodiment.

FIG. 10 is a close-up schematic cross-sectional side view illustration of a portion of display panel including an LED sealing structure in accordance with an embodiment.

FIG. 11A is a close-up schematic cross-sectional side view illustration of a portion of display panel including an RDL scaling structure and PCD structure in accordance with an embodiment.

FIG. 11B is a schematic top plan view illustration of a display panel including a metal seal ring and multiple loop PCD structure in accordance with an embodiment.

FIG. 11C is a schematic top plan view illustration of a display panel including a metal seal ring and single loop PCD structure in accordance with an embodiment.

FIG. 12A is a close-up schematic cross-sectional side view illustration of a portion of display panel including a hybrid metal seal ring and PCD structure in accordance with an embodiment.

FIG. 12B is a schematic top plan view illustration of a display panel including a hybrid metal seal ring and multiple loop PCD structure in accordance with an embodiment.

FIG. 12C is a schematic top plan view illustration of a display panel including a hybrid metal seal ring and single loop PCD structure in accordance with an embodiment.

FIG. 13 is an isometric view of a mobile telephone in accordance with an embodiment.

FIG. 14 is an isometric view of a tablet computing device in accordance with an embodiment.

FIG. 15 is an isometric view of a wearable device in accordance with an embodiment.

FIG. 16 is an isometric view of a laptop computer in accordance with an embodiment.

FIG. 17 is a system diagram of a portable electronic device in accordance with an embodiment.

### DETAILED DESCRIPTION

Embodiments describe electronic device structures and methods of fabrication in which a display panel of the electronic device includes an array of pixel driver chips, a redistribution layer (RDL) over the array of pixel driver chips and an array of LEDs mounted on the RDL. The RDL may include a metal seal ring within a border region. Additional inorganic barrier layers can also be formed underneath and/or over the metal seal ring. Together the metal seal ring and inorganic barrier layers can provide a sealed box structure that serves to mitigate moisture ingress to organic layers within the RDL and mitigate metal wiring layer corrosion within the RDL. The metal seal ring may additionally provide mechanical integrity and crack protection.

In accordance with embodiments, the display panels can be fabricated using an “LED first” or “LED last” fabrication sequence. For example, in an “LED last” fabrication sequence an array of pixel driver chips can be mounted onto a carrier, followed by encapsulation within a planarization layer, formation of an RDL, and mounting of the array of LEDs on the RDL. In an “LED first” fabrication sequence an array of LEDs can be placed, followed by deposition of a sidewall encapsulation layer for gap fill, formation of an RDL, and transfer of the pixel driver chips. Alternatively, the LEDs and pixel driver chips can both be surface mounted onto an existing RDL. In yet another variation, an RDL can be formed over both LEDs and pixel driver chips. In any of the configurations the RDL can be formed using thin film techniques. For example, the RDL may have a plurality of dielectric layers and metal wiring layers. The dielectric layers for example, may be organic materials deposited using low-cost deposition techniques such as slot coating, spin coating, etc. The metal wiring layers may also be formed using low-cost deposition techniques such as physical vapor deposition, though other techniques such as metal-organic chemical vapor deposition (MOCVD) or plating techniques may be used.

In one aspect, it has been observed that moisture ingress into the organic dielectric layers of the RDL may corrode the RDL metal wiring layers causing cracks and metal oxide bridging between traces of the metal wiring layers, and eventual device failure. This may be attributed to the RDLs including more organic materials than in conventional TFT substrates. Furthermore, unlike traditional OLED or LCD display substrates the scaling structures (e.g., metal seal ring, inorganic barrier layers) in accordance with embodiments may be designed to prevent ingress of moisture into the RDL to mitigate metal corrosion within as opposed to protecting organic emission layers such as with OLED, or potentially transistors of a TFT substrate. Thus, in some embodiments the sealed box structures do not encase the LEDs of the display panel.

In accordance with embodiments, panel crack/corrosion detector (PCD) structures can also be integrated into the RDL in order to provide an electrical test for panel cracking or corrosion. For example, the PCD structure can be electrically connected with a control circuit for the display panel to test for open/shorts. Such PCD structures can be provided within the RDL metal wiring layers laterally adjacent to the metal seal ring. Alternatively, the metal seal ring may additionally function as a PCD structure. Alternatively, the metal seal ring can be connected to a control circuit to test electrical performance of the mean seal ring and detect the structural integrity and manufacturing defects of the metal seal ring structure and/or PCD.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

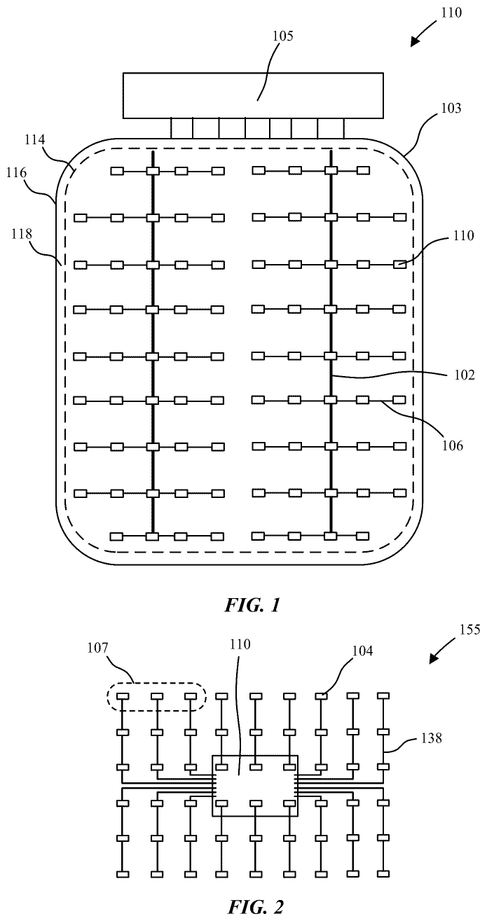

FIG. 1 is schematic top view illustration of a tile-based display panel 103 including spline-corners in accordance with an embodiment. For example, the spline-corners may be rounded edges optionally folded into a curved 3D film contour. The tile-based display panels may include an arrangement of pixel driver chips 110 to drive local matrices of pixels. FIG. 2 is an example of a matrix tile 155 including a pixel driver chip 110 to switch and drive multiple pixels 107 of LEDs 104. This may include either a direct drive approach, where every pin of the pixel driver chip 110 is connected to one LED, or a local passive matrix (LPM) arrangement in which pins of the pixel driver chips 110 can be connected to strings of LEDs. In an embodiment, this may be an LPM tile 155.

LED 104 and pixel driver chip 110 sizes in accordance with embodiments are scalable from macro to micro sized. In an embodiment, the pixel driver chips 110 may have a length with a maximum dimension of less than 400 μm, or even less than 200 μm. Micro LEDs in accordance with embodiments may have a maximum dimension of less than 100 μm, or even less than 20 μm, such as less than 10 μm, or even less than 5 μm for displays with high resolution and pixel density.

In particular, the arrangement of pixel driver chips 110 in accordance with embodiments can remove the requirement for driver ledges on the edges of a display panel 103. As a result, the display panel 103 may have reduced borders outside of the display area. The configuration may facilitate the formation of display panels with curved edges, as well as internal cutouts. In addition, the configuration may facilitate modular arrangements, including micro arrangements, of display tiles. Generally, the control circuit 105 may be coupled to an edge of the display panel 103. Bus columns of global routing lines 102 may extend from the control circuit 105 to supply global signals to the display panel 103. For example, the global routing lines 102 may include at least data clock lines, emission clock lines, and vertical selection token (VST) lines. The global routing lines are coupled to a plurality of “hybrid” pixel driver chips, and together form a backbone of the display. The corresponding backbone hybrid pixel driver chips receive the global signals and then transmit manipulated signals to their corresponding rows of row lines 106 connected to the other pixel driver chips 110 within the same row. For example, the global data clock and emission clock signals may be converted to manipulated signals and transmitted to the row of pixel driver chips 110 along manipulated data clock lines and manipulated emission clock lines. For example, the manipulated signals may include only the necessary information for the particular row.

The tile-based display panels in accordance with embodiments may have various arrangements of display tiles. For example, the display tiles may be arranged side-by-side (horizontally), stacked (vertically), both, as well as other configurations. Additionally, the bus columns of global routing lines 102 may be aligned and connected for stacked display tiles.

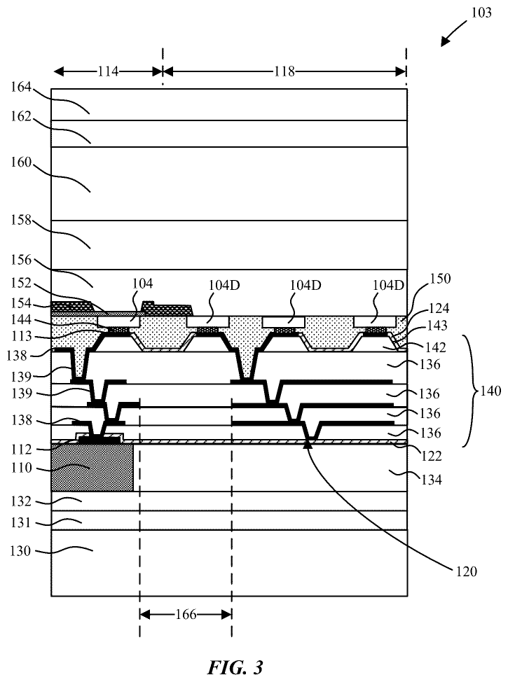

FIG. 3 is a close-up schematic cross-sectional side view illustration of a portion of display panel 103 including embedded pixel driver chips 110 in accordance with an embodiment. Method of manufacture may include transferring an array of pixel driver chips 110 to a display substrate 130 or other carrier. For example, the display substrate 130 may be a flexible substrate, such as glass, polyimide, etc. A stress compensation layer 131 may optionally be formed over the display substrate 130 to assist with warpage control. For example, the stress compensation layer may be an inorganic or metal layer. An adhesion layer 132 may optionally be formed on the display substrate 130 to receive the pixel driver chips 110. Transfer may be accomplished using a pick and place tool. In an embodiment, a back side (non-functionalized) side is placed onto the adhesion layer 132, with the front side (active side, including contact pads 112) placed face up. The contact (terminal) pads 112 may be formed before or after transfer. As illustrated, a planarization layer 134 can be formed around the pixel driver chips 110, for example, to secure the pixel driver chips 110 to the display substrate 130, and to provide step coverage for additional routing. Suitable materials for planarization layer 134 include polymers, spin on glass, oxides, etc. In an embodiment, planarization layer is a thermoset material such as acrylic, epoxy, benzocyclobutene (BCB), etc.

A redistribution layer (RDL) 140 may then be formed over the array of pixel driver chips 110. The RDL 140 may, for example, fan out from the contact (terminal) pads 112 and additionally may include routing to/from control circuit 105. Following formation of the RDL 140 the array of LEDs 104 can be mounted onto landing pads 113 (e.g., driver pads) of the RDL, for example with a solder bonding material 144 or other suitable bonding material. Generally, the LEDs in accordance with embodiments may be vertical micro LEDs including a p-n diode, a top surface (top electrode side), a bottom contact (bottom electrode side) and sidewall of the p-n diode. For example, the p-n diodes may be formed of inorganic semiconductor materials, such as III-V or II-VI materials. Exemplary materials include nitride-based semiconductors (e.g., GaN) and phosphorous-based semiconductors (e.g., AlInGaP, InGaP). Alternatively, the LEDs may be horizontal micro LEDs.

A sidewall encapsulation layer 150 can then be formed around the LEDs 104. The sidewall encapsulation layer 150 may help secure the LEDs 104 in place and also function as a planarization layer. Additionally, the sidewall encapsulation layer 150 may optionally include particles for light scattering. Sidewall encapsulation layer 150 may be formed using a suitable technique such as slot coating in order to fill any gaps and provide a level top surface. Suitable materials include polymers such as polyimide, epoxy, benzocyclobutene (BCB), acrylics such as poly (methyl methacrylate) (PMMA), etc.

A top transparent or semi-transparent electrically conductive layer(s) 152 can then be deposited to provide electrical connection from the top sides of the LEDs 104 to the voltage power supply lines, or cathodes. Suitable materials include transparent conductive oxides (TCOs), conductive polymers, thin transparent metal layers, etc.

The illustrated stack-up through formation of the top transparent or semi-transparent electrically conductive layer(s) 152 may form an emissive stack. The display panel 103 may optionally include additional layers. For example, a black matrix layer 154 can be formed over the emissive stack. In accordance with embodiments, the black matrix layer 154 may reduce internal reflection (e.g., specular reflection) of the emissive stack, inclusive of reflection from the electrical routing and pixel driver chips 110. Increased area of the black matrix layer may correspond to a decrease in reflectivity of the emissive stack. The black matrix layer 154 may also define an optical opening over a corresponding LED 104. The black matrix layer may be formed of suitable materials, such as polymer and glass and may include organic dye-based absorbers (including mixed molecule dyes) as well as pigment-based absorbers, or particles to absorb a specific visible wavelength spectrum. In an embodiment, the black matrix layer includes carbon-black particles. Furthermore, an overcoat layer 156 can be formed over the emissive stack. Overcoat layer 156 may be an optically clear material, such as an acrylate, silicone, etc., and may have a variety of functions, such as mechanical protection, levelling for bonding (e.g., with polarizer layer 160), and chemical passivation (e.g., from environment).

For example, a polarizer layer 160 may be applied to the emissive stack with an optically clear adhesive layer 158 (e.g., acrylate, silicone-based, etc.). A cover plate 164 (e.g., glass, sapphire, polymer) may then be attached over the polarizer layer 160 with a second optically clear adhesive layer 162.

The RDL 140 in accordance with embodiments may include a plurality of redistribution lines 138, contact via lines 139, and a plurality of dielectric layers 136 separating the various metal layer levels of the redistribution lines 138. For example, redistribution lines 138 and contact via lines may be metal lines (e.g., Cu, Al, etc.). In the illustrated embodiments, the redistribution lines 138 and contact via lines 139 are formed using thin film techniques, and the contact via lines 139 may extend into via openings in the dielectric layers 136. When utilizing thin film techniques, the contact via lines 139 may form an outline conforming to the via openings. Alternatively, other plating techniques can be utilized so that metal vias completely fill the via openings, though this may be accompanied by additional process operations, including metal planarization.

The dielectric layers 136 may be formed of suitable insulating materials including oxides (e.g., SiOx), nitrides, polymers, etc. In accordance with particular embodiments the dielectric layers 136 may be formed of organic materials including polymers such as polyimide, epoxy, benzocyclobutene (BCB), acrylics such as poly (methyl methacrylate) (PMMA), etc. In accordance with embodiments, RDL 140 includes one or more of the plurality global routing lines 102 and row lines 106 for signal and power (e.g., data signal, row synchronization signal, frame synchronization signal, and vertical synchronization token (VST), Vdd, etc.).

In some embodiments, an uppermost dielectric layers 136 can be a patterned bank layer with an arrangement of bank structures 142 onto which the LEDs 104 can be mounted, for example with a solder bonding material 144. RDL 140 additionally includes landing pads 113 for LEDs 104, the landing pads 113 connected with the redistribution lines 138. In accordance with some embodiments, strings of LEDs may be connected to a corresponding interconnect (e.g., string, or line). As shown, the landing pads 113 can be connected with (or part of) redistribution lines 138.

In accordance with embodiments, various sealing structures may be integrated with the RDL 140 due to high organic material content, which may be particularly susceptible to moisture ingress and metal corrosion. The sealing structures may provide a sealed box or hermetic seal around the RDL 140 and may include various combinations of inorganic layers and metal seal rings formed by the metal wiring layers forming the redistribution lines 139 and via lines 139 of the RDL.

In an embodiment an electronic device includes a display panel 103 including a display area 114, a peripheral edge 116 surrounding the display area, and a border region 118 along the peripheral edge and surrounding the display area. The display panel 103 further includes an array of pixel driver chips 110, an RDL 140 over the array of pixel driver chips, and an array of LEDs 104 mounted on the RDL with the display area 114. The RDL may additionally include a metal seal ring 120 in the border region 118. In an embodiment, a lower inorganic sealing layer 122 (e.g., SiNₓ, SiONₓ, SiO₂, Al₂O₃, etc.) is formed beneath the RDL 140 and the metal seal ring 120 contacts the lower inorganic sealing layer 122. In the specific embodiment illustrated in FIG. 3, the lower inorganic sealing layer 122 extends partially over each pixel driver chip of the array of pixel driver chips. In this manner, the lower inorganic sealing layer 122 and the pixel driver chips 110 together form a lower seal, and the metal seal ring 120 forms a side seal. Still referring to FIG. 3, the display panel 103 may further include an upper inorganic sealing layer 124 (e.g., SiNₓ, SiONₓ, SiO₂, Al₂O₃, etc.) on the RDL 140, where the upper inorganic sealing layer 124 contacts the metal seal ring 120. The upper inorganic sealing layer 124 and uppermost metal wiring layer including landing pads 113, routing lines 138 and via lines 139 together may form an upper seal to complete the scaled box around the RDL 140 organic layers. The upper inorganic sealing layer 124 may be formed before or after the uppermost wiring layer of the plurality of metal wiring layers in the RDL. For example, the upper inorganic sealing layer 124 may span partially over an uppermost wiring layer of the plurality of metal wiring layers, or alternatively an uppermost wiring layer of the plurality of metal wiring layers may partially span over the upper inorganic scaling layer 124.

While not required, the RDL 140 may include a plurality of bank structures 142, which may facilitate mounting of the array of LEDs 104. With such a topography, the upper inorganic scaling layer 124 may partially span over the plurality of bank structures 142, and along sidewalls 143 thereof, across both the display area 114 and border region 118. Likewise, a portion of the upper wiring layer of the metal seal ring 120 may also partially span over a portion of the plurality of bank structures 142, and along sidewalls 143 thereof, in the border region 118.

Still referring to FIG. 3, in some embodiments the display panel 103 may additionally include a plurality of LEDs mounted on the RDL 140 within the border region 118. For example, these may be dummy LEDs 104D that are not functionally connected with the array of pixel driver chips 110. For example, the dummy LEDs 104D may not be connected with contact pads 112, of the pixel driver chips, or alternatively are not connected with the top transparent or semi-transparent electrically conductive layer(s) 152. One or more of the dummy LEDs 104D may or may not be connected with the metal seal ring 120. The presence of dummy LEDs 104D may be an artifact of the LED transfer sequences and display panel 103 shape. For example, transfer stamps with a rectangular array of transfer heads may be used to transfer corresponding rectangular arrays of LEDs to the display panel, though the display area 114 may have a non-rectangular shape, or other mismatch that necessitates the transfer of additional LEDs into the border region. In some embodiments, the metal seal ring 120 may be connected with a low voltage source, or ground. The array of pixel driver chips 110 may also be optionally connected with the low voltage source, or ground, separately or through the metal seal ring 120.

The metal seal ring 120 may optionally be coupled with the electrical wiring that is coupled with the array of pixel driver chips 110, or alternatively completely electrically separate. In some embodiments a substantial portion, or all, of the metal seal ring 120 metal wiring layers is separated from the metal wiring layers of the RDL 140 that is electrically connected with the array of pixel driver chips 110 by a gap 166 where there is no metal wiring. The gap 166 may function as both a barrier for metal oxide bridging, and corrosion promulgation, as well as a discontinuity to limit crack propagation. For example, the gap may be up to several microns depending upon requirements of the display panel. In an embodiment, the gap is 1-2 microns wide. In other embodiments no gap exists.

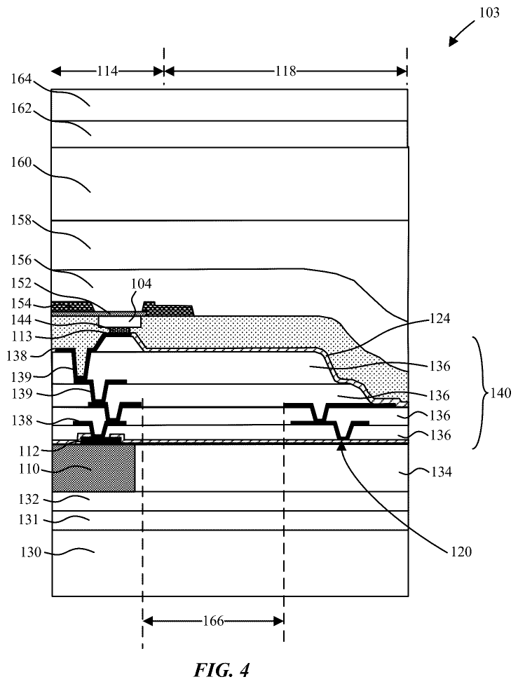

In accordance with embodiment the RDL 140 may have a reduced thickness in the border region 118 where electrical routing requirements may be reduced. In the embodiment illustrated in FIG. 3 the RDL includes 140 a plurality of metal wiring layers and a plurality of organic dielectric layers 136, and the upper inorganic scaling layer 124 connects to an uppermost wiring layer of the plurality of metal wiring layers. FIG. 4 is a close-up schematic cross-sectional side view illustration of a portion of display panel including an RDL sealing structure in which the RDL 140 has a reduced thickness in the border region 118 in accordance with an embodiment. As shown, the lateral extension of one or more of the dielectric layer 136 and metal wiring layers may be reduced. In this manner overlying layers may also laterally surround (partially or completely) one or more underlying layers. In the particular embodiment illustrated the RDL 140 includes a plurality of metal wiring layers and a plurality of organic dielectric layers 136, and the upper inorganic scaling layer 124 connects to a metal wiring layer of the plurality of metal wiring layers below an uppermost wiring layer of the plurality of metal wiring layers.

It is to be appreciated that the metal seal rings 120 in accordance with embodiments can be full seal ring structures that completely surround the display area 114, or partial seal ring structures that do not completely surround the display area and may be formed around some but not all sides of the display area 114.

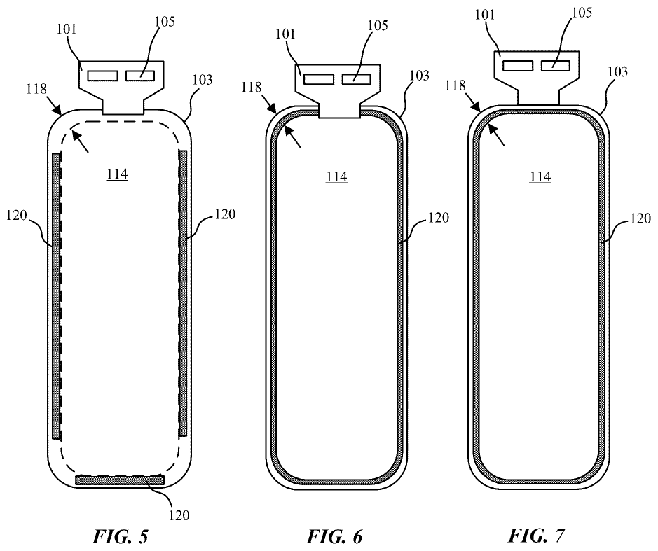

FIGS. 5-7 are schematic top plan view illustrations of display panels including various metal seal ring locations in accordance with embodiments. As shown, metal seal ring 120 locations are shown with the shaded areas. Metal seal ring 120 location may be determined based upon shape, as well as external connection requirements, such as an optional flexible printed circuit board (PCB) 101 for control circuit 105 connection. In the embodiment illustrated in FIG. 5, the metal seal ring 120 locations are substantially along a plurality of sides of the display area 114. In the embodiment illustrated in FIG. 6, the metal seal ring 120 substantially surround the display area 114 though is broken to accommodate the flexible PCB 101 attachment. In the embodiment illustrated in FIG. 7, the metal seal ring 120 completely surrounds the display area 114. In each of the embodiments, the metal seal ring continuously extends substantially along at least one side of the display area 114, and also extends along at a pair of laterally opposite sides of the display area 114.

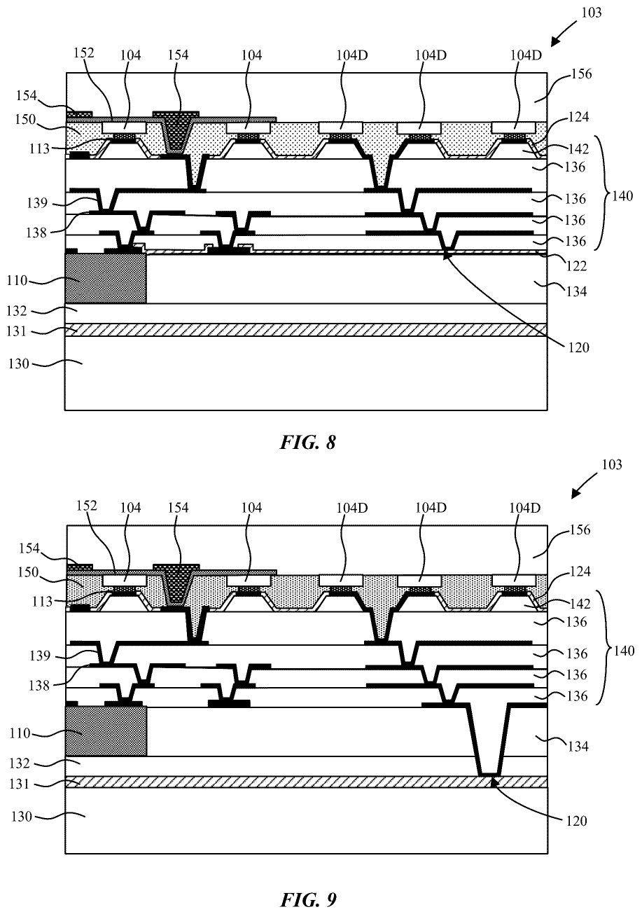

Referring now to FIGS. 8-10 close-up schematic cross-sectional side view illustrations are provided for additional sealing structures in accordance with embodiments. While illustrated separately it is to be appreciated that many of the structures illustrated and described with regard to FIGS. 8-10 are combinable with other structures described herein. FIG. 8 is a close-up schematic cross-sectional side view illustration of a portion of display panel including an RDL scaling structure accordance with an embodiment. In particular, FIG. 8 is similar to the structure previously illustrated and described with regard to FIG. 4, though for clarity all layers are not illustrated. As shown, trenches may also be formed through the sidewall encapsulation layer 150 for electrical connection with the top transparent or semi-transparent electrically conductive layer(s) 152 and a wiring layer of the RDL 140, such as the uppermost wiring layer, which in turn can also be electrically connected with one or more pixel driver chips 110. Thus, the pixel driver chips 110 may be electrically connected with both the landing pads 113 and the top transparent or semi- transparent electrically conductive layer(s) 152.

FIG. 9 is a close-up schematic cross-sectional side view illustration of a portion of display panel including an RDL sealing structure extending beneath the pixel driver chips 110 in accordance with an embodiment. As shown, when forming the RDL 140 a trench may be formed through both the planarization layer 134 and optional adhesive layer 132 to contact the stress compensation layer 131. Where the stress compensation layer 131 is formed of an inorganic material (e.g., SiNₓ, SiONₓ, SiO₂, Al₂O₃, etc.) or metal this provides a lower seal that extends beneath the pixel driver chips.

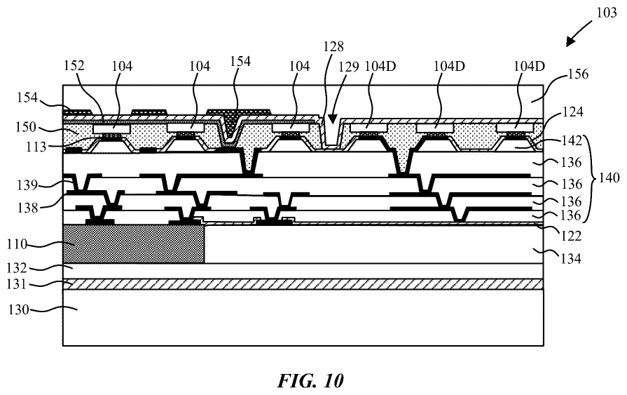

FIG. 10 is a close-up schematic cross-sectional side view illustration of a portion of display panel including an LED sealing structure in accordance with an embodiment. In the particular embodiment illustrated, after formation of the top transparent or semi-transparent electrically conductive layer(s) 152 a top inorganic sealing layer 128 can be formed and may span over the array of LEDs 104 in the display area, and optionally over the dummy LEDs 104 in the border region. As shown, a trench 129 is formed through the sidewall encapsulation layer 150 to the upper inorganic sealing layer 124, and the top inorganic sealing layer 128 spans over the sidewall encapsulation layer and within the trench 129 to contact the upper inorganic sealing layer. Thus, a scaled box structure can be formed with the tip inorganic sealing layer 128, the upper inorganic scaling layer 124 and upper wiring layer of the RDL 140.

Up until this point various sealing structures have been described including a metal seal ring 120 and passivation layers. The metal seal rings 120 can for example be electrically floating, or connected to a low voltage source or ground for example to dissipate charge build-up. In accordance with embodiments, detectors can also be integrated to electrically test for panel cracks and corrosion. For example, a panel crack/corrosion detector (PCD) 170 can be integrated with into trace lines of one or more of the metal layers in the RDL 140 for any of the various scaling structures described herein. Alternatively, the metal seal ring can be connected to a control circuit to test electrical performance of the mean seal ring and detect the structural integrity and manufacturing defects of the metal seal ring structure and/or PCD.

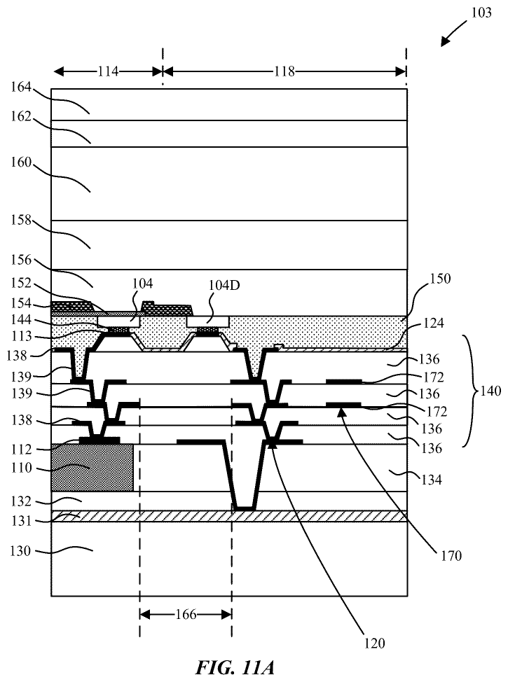

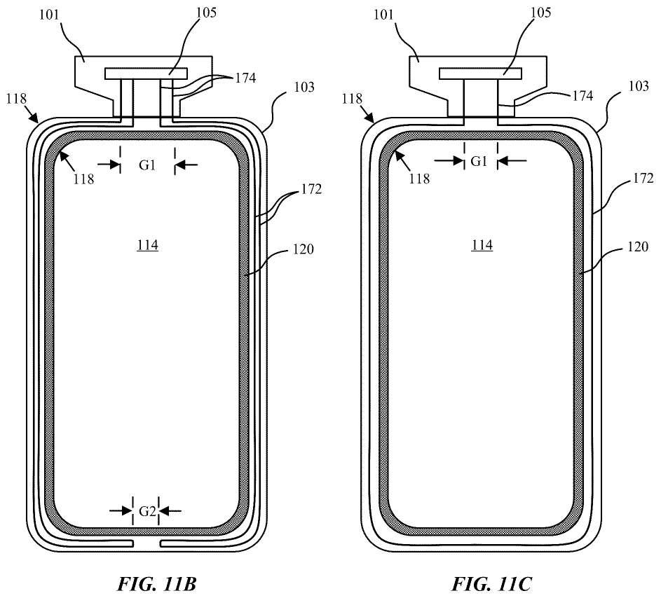

Referring now to FIGS. 11A-11C, FIG. 11A is a close-up schematic cross-sectional side view illustration of a portion of display panel including an RDL sealing structure and PCD structure in accordance with an embodiment; FIG. 11B is a schematic top plan view illustration of a display panel including a metal seal ring and multiple loop PCD structure in accordance with an embodiment; FIG. 11C is a schematic top plan view illustration of a display panel including a metal seal ring and single loop PCD structure in accordance with an embodiment. As shown, the PCD structure 170 can include one or more trace lines 172 formed laterally adjacent to, and exterior from, the metal seal ring 120 for example so that they run around a perimeter of the metal seal ring 120. The PCD structure 170 can additionally include routing 174 that connects the one or more trace lines 172 with the control circuit(s) 105. In this manner, the logic within control circuit 105 may potentially be used to detect crack or corrosion prior to propagating to the metal seal ring 120. For example, this may be by comparing a measured current or voltage value with binned current or voltage information stored in a lookup table within the control circuit 105.

The particular embodiment illustrated in FIG. 11A is similar to that previously illustrated and described with regard to FIG. 9 though structures related to dummy LEDs 104D have been omitted. As shown, the PCD structure 170 can include one or more trace lines 172 from one or more metal layer levels of RDL 140. For example, the trace lines 172 can be formed similarly as the redistribution lines 138. The trace lines 172 may additionally be physically and electrically separate from the metal seal ring 120. In the particular embodiment illustrated in FIG. 11B the trace lines 172 can form multiple loops, each connected to the control circuit(s) 105 with routing 174, which can be combination of on-panel and/or off-panel routing. As shown in FIG. 11B, a consequence of multiple loops can result in a gap distance G1, or gap distance G2, where the trace lines 172 from separate loops do not overlap. In the embodiment illustrated in FIG. 11C, the gap distance G2 can be eliminated with potentially only gap distance G1 remaining. The gap distances G1, G2 may further be eliminated by forming the trace lines 172 in different metal layers. The PCD structure 170 in accordance with embodiments can be used for to detect opens or shorts within the loop(s), which may correspond to panel cracking or corrosion.

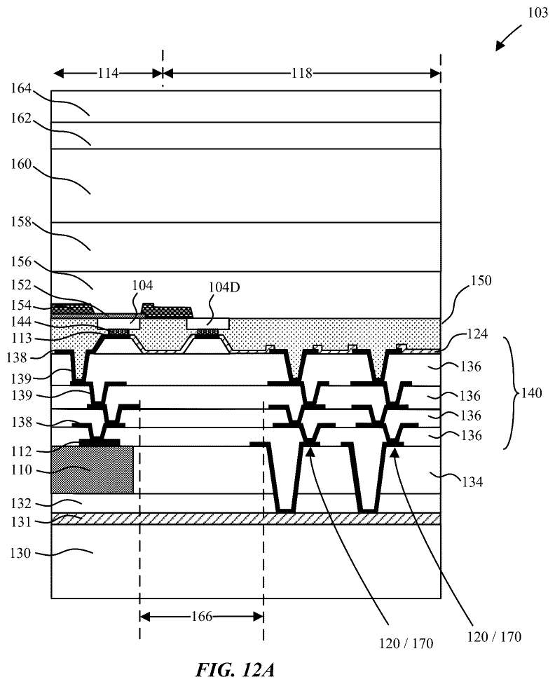

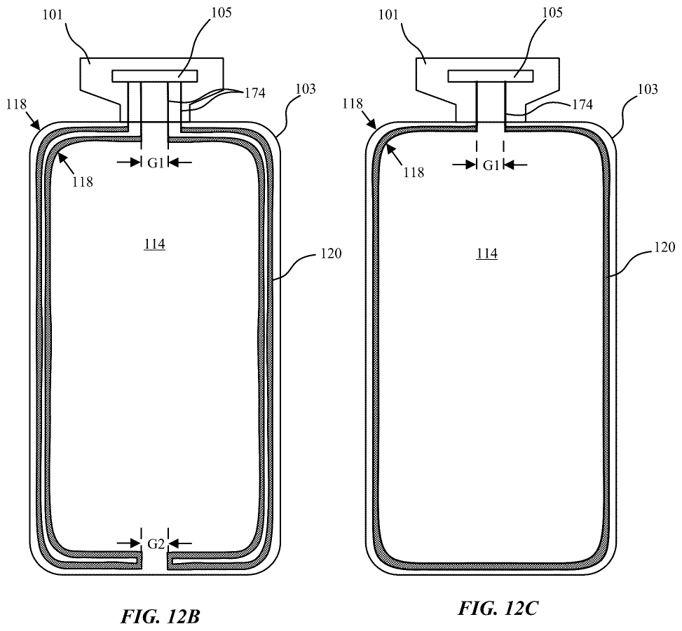

Referring now to FIGS. 12A-12C, a close-up schematic cross-sectional side view illustration and schematic top plan view illustrations are provided similar to FIGS. 11A-11C, with instead a hybrid metal seal ring and PCD structure in accordance with embodiments. As shown, one or more metal seal rings 120 can be connected to routing 174 and control circuit(s) 105 to integrate with PCD structure(s) 170. In this manner, the structural integrity and manufacturing defects of the metal seal ring structure can be detected. The logic within control circuit 105 may potentially be used compare a measured current or voltage value of the metal seal ring(s) with binned current or voltage information stored in a lookup table within the control circuit 105.

It is to be appreciated that the PCD structures can be integrated with any of the scaling structures described herein, and are not limited to the specific orientations or stack-ups shown in FIGS. 11A-12C.

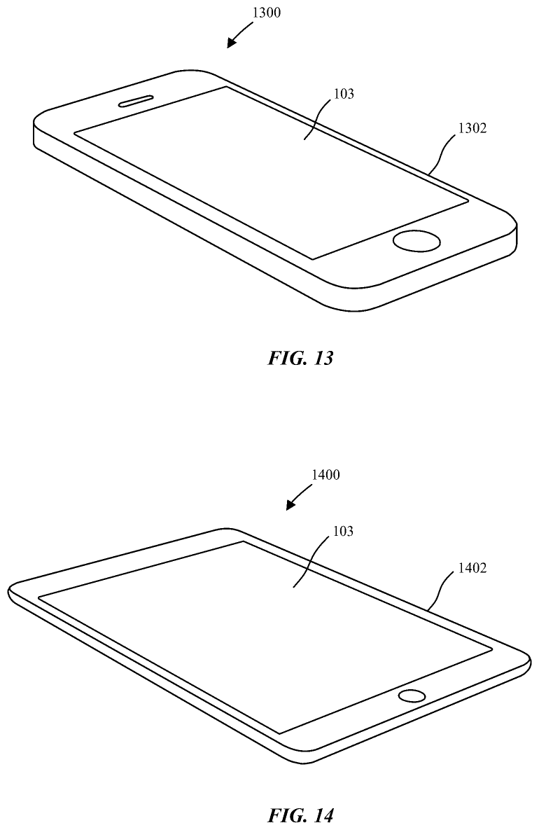

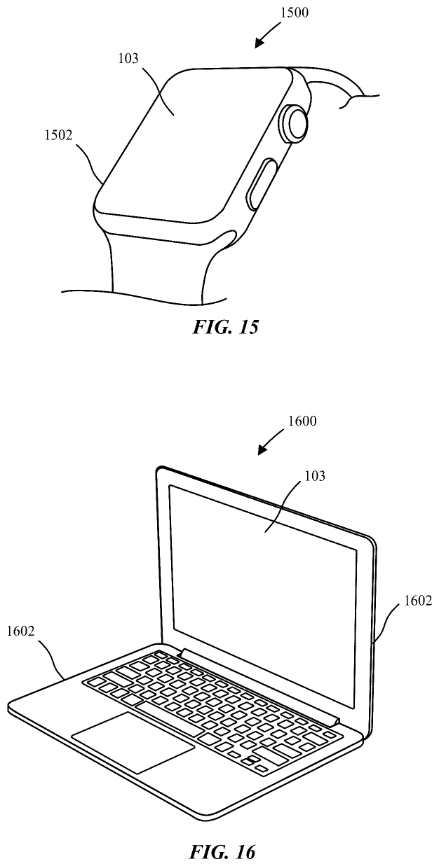

FIGS. 13-16 illustrate various portable electronic systems in which the various embodiments can be implemented. FIG. 13 illustrates an exemplary mobile telephone 1300 that includes a display panel 103 packaged in a housing 1302. FIG. 14 illustrates an exemplary tablet computing device 1400 that includes a display panel packaged in a housing 1402. FIG. 15 illustrates an exemplary wearable device 1500 that includes a display panel 103 packaged in a housing 1502. FIG. 16 illustrates an exemplary laptop computer 1600 that includes a display panel 103 packaged in a housing 1602.

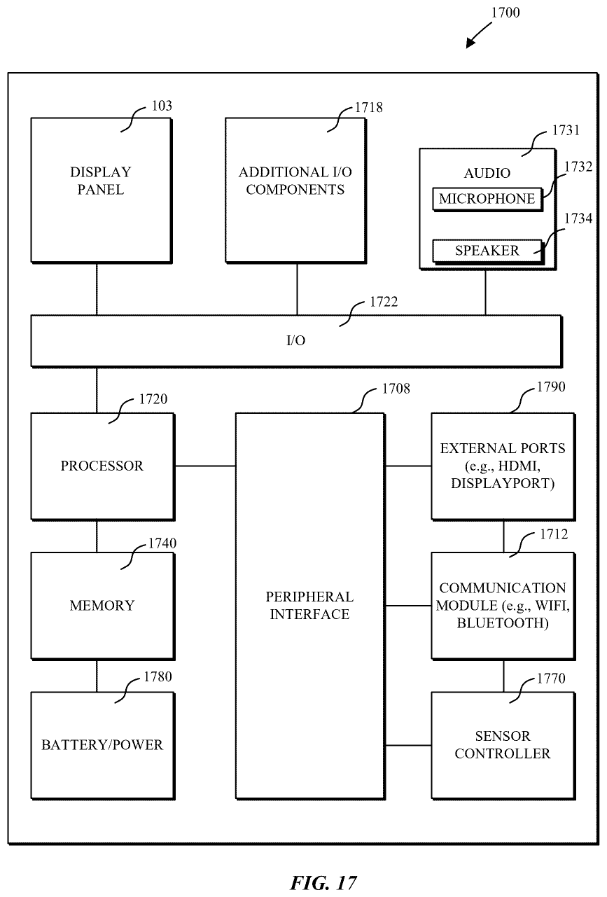

FIG. 17 illustrates a system diagram for an embodiment of a portable electronic device 1700 including a display panel 103 described herein. The portable electronic device 1700 includes a processor 1720 and memory 1740 for managing the system and executing instructions. The memory includes non-volatile memory, such as flash memory, and can additionally include volatile memory, such as static or dynamic random access memory (RAM). The memory 1740 can additionally include a portion dedicated to read only memory (ROM) to store firmware and configuration utilities.

The system also includes a power module 1780 (e.g., flexible batteries, wired or wireless charging circuits, etc.), a peripheral interface 1708, and one or more external ports 1790 (e.g., Universal Serial Bus (USB), HDMI, Display Port, and/or others). In one embodiment, the portable electronic device 1700 includes a communication module 1712 configured to interface with the one or more external ports 1790. For example, the communication module 1712 can include one or more transceivers functioning in accordance with IEEE standards, 3GPP standards, or other communication standards, 4G, 5G, etc. and configured to receive and transmit data via the one or more external ports 1790. The communication module 1712 can additionally include one or more WWAN transceivers configured to communicate with a wide area network including one or more cellular towers, or base stations to communicatively connect the portable electronic device 1700 to additional devices or components. Further, the communication module 1712 can include one or more WLAN and/or WPAN transceivers configured to connect the portable electronic device 1700 to local area networks and/or personal area networks, such as a Bluetooth network.

The portable electronic device 1700 can further include a sensor controller 1770 to manage input from one or more sensors such as, for example, proximity sensors, ambient light sensors, or infrared transceivers. In one embodiment the system includes an audio module 1731 including one or more speakers 1734 for audio output and one or more microphones 1732 for receiving audio. In embodiments, the speaker 1734 and the microphone 1732 can be piezoelectric components. The portable electronic device 1700 further includes an input/output (I/O) controller 1722, a display panel 103, and additional I/O components 1718 (e.g., keys, buttons, lights, LEDs, cursor control devices, haptic devices, and others). The display panel 103 and the additional I/O components 1718 may be considered to form portions of a user interface (e.g., portions of the portable electronic device 1700 associated with presenting information to the user and/or receiving inputs from the user).

In utilizing the various aspects of the embodiments, it would become apparent to one skilled in the art that combinations or variations of the above embodiments are possible for forming an electronic device with sealed RDL. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic device including:
a display panel including a display area, a peripheral edge surrounding the display area, and a border region along the peripheral edge and surrounding the display area;
wherein the display panel comprises:
an array of pixel driver chips;
a redistribution layer (RDL) over the array of pixel driver chips; and
an array of light-emitting diodes (LEDs) mounted on the RDL within the display area;
wherein the RDL includes a metal seal ring in the border region.

2. The electronic device of claim 1, wherein the metal seal ring continuously extends substantially along at least one side of the display area.

3. The electronic device of claim 2, wherein the metal seal ring continuously extends along opposite sides of the display area.

4. The electronic device of claim 1, wherein the RDL includes a plurality of metal wiring layers and a plurality of organic dielectric layers.

5. The electronic device of claim 1, further comprising a lower inorganic sealing layer beneath the RDL, wherein the metal seal ring contacts the lower inorganic sealing layer.

6. The electronic device of claim 5, wherein the lower inorganic sealing layer extends partially over each pixel driver chip of the array of pixel driver chips.

7. The electronic device of claim 1, further comprising an inorganic or metal stress compensation layer beneath the RDL and the array of pixel driver chips, wherein the metal seal ring contacts the stress compensation layer.

8. The electronic device of claim 1, further comprising an upper inorganic sealing layer on the RDL, wherein the upper inorganic sealing layer contacts the metal seal ring.

9. The electronic device of claim 8, wherein:
the RDL includes a plurality of metal wiring layers and a plurality of organic dielectric layers; and
the upper inorganic sealing layer connects to a metal wiring layer of the plurality of metal wiring layers below an uppermost wiring layer of the plurality of metal wiring layers.

10. The electronic device of claim 8, wherein:
the RDL includes a plurality of metal wiring layers and a plurality of organic dielectric layers; and
the upper inorganic sealing layer connects to an uppermost wiring layer of the plurality of metal wiring layers.

11. The electronic device of claim 8, wherein:
the RDL includes a plurality of metal wiring layers and a plurality of organic dielectric layers; and
the upper inorganic sealing layer spans partially over an uppermost wiring layer of the plurality of metal wiring layers.

12. The electronic device of claim 8, wherein:
the RDL includes a plurality of metal wiring layers and a plurality of organic dielectric layers; and
an uppermost wiring layer of the plurality of metal wiring layers spans partially over the upper inorganic sealing layer.

13. The electronic device of claim 8, wherein the RDL comprises a plurality of bank structures, and the array of LEDs is mounted on the plurality of bank structures.

14. The electronic device of claim 13, wherein the upper inorganic sealing layer partially spans over the plurality of bank structures.

15. The electronic device of claim 14, wherein an upper wiring layer of the metal seal ring partially spans over a portion of the plurality of bank structures in the border region.

16. The electronic device of claim 8, further comprising a top inorganic sealing layer spanning over the array of LEDs.

17. The electronic device of claim 16, wherein the array of LEDs is embedded in a sidewall encapsulation layer, and the top inorganic sealing layer spans over the sidewall encapsulation layer.

18. The electronic device of claim 17, further comprising a trench through the sidewall encapsulation layer to the upper inorganic sealing layer, wherein the top inorganic sealing layer spans within the trench to contact the upper inorganic sealing layer.

19. The electronic device of claim 1, further comprising a plurality of LEDs mounted on the RDL within the border region.

20. The electronic device of claim 19, wherein the plurality of LEDs mounted on the RDL within the border region are not functionally connected with the array of pixel driver chips.

21. The electronic device of claim 1, wherein the RDL includes one or more trace lines around a perimeter of the metal seal ring, wherein the trace lines are electrically connected to a control circuit to test electrical performance of the one or more trace lines.

22. The electronic device of claim 1, wherein the metal seal ring is electrically connected to a control circuit to test electrical performance of the metal seal ring.
